(19) United States
(12) Patent Application Publication
(10) Pub. No.: US 2020/0028058 A1
(43) Pub. Date: Jan. 23, 2020

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP)

(73) Assignee: TDK CORPORATION, Tokyo (JP)

(21) Appl. No.: 16/512,715

(22) Filed: Jul. 16, 2019

(30) Foreign Application Priority Data
Jul. 20, 2018 (JP) 2018-136957

(51) Int. Cl. H01L 35/32; H01L 35/30; H01L 35/34; H02N 11/00; H01L 35/22

(52) U.S. Cl. CPC H01L 35/32; H01L 35/30; H01L 35/22; H02N 11/00; H01L 35/34

(57) ABSTRACT

A thermoelectric conversion device includes, thermoelectric conversion element arrays each having thermoelectric conversion elements lined up in a first direction intersecting a second direction, a first electrode provided at one end side of thermoelectric conversion element in the second direction, a second electrode provided at other end side of thermoelectric conversion element in the second direction, a first wiring disposed between one thermoelectric conversion element and other thermoelectric conversion element adjacent in the first direction and electrically connected between the first electrodes or the second electrodes of the one thermoelectric conversion element and the other thermoelectric conversion element, and a second wiring electrically connected between the first electrodes or the second electrodes of the thermoelectric conversion elements located at one-end-most sides or other-end-most sides of one thermoelectric conversion element array and other thermoelectric conversion element array in the first direction.

### BACKGROUND

The disclosure relates to a thermoelectric conversion device. Priority is claimed on Japanese Patent Application No. 2018-136957, filed Jul. 20, 2018, the content of which is incorporated herein by reference.

For example, exhaust heat from an internal combustion engine, a combustion device, or the like is lost without being used. Thus, the use of such exhaust heat has been focused on in recent years from the viewpoint of energy saving. In particular, research on thermoelectric conversion devices capable of converting heat into electricity has been actively conducted (see, for example, PCT International Publication No. WO/2011/065185).

Specifically, the following PCT International Publication No. WO/2011/065185 discloses a thermoelectric conversion module (a thermoelectric conversion device) including: an insulating substrate; a plurality of thermoelectric conversion material films made of either one of an n-type thermoelectric conversion material and a p-type thermoelectric conversion material and disposed apart from each other on a first surface of the insulating substrate; a first electrode and a second electrode formed apart from each other on each thermoelectric conversion material film; a first heat transfer member disposed on a first surface side of the insulating substrate and provided with a protrusion in contact with the first electrode; and a second heat transfer member disposed on a second surface side of the insulating substrate and provided with a protrusion in contact with a region which is on the second surface of the insulating substrate and corresponds to the second electrode.

Also, the thermoelectric conversion module is configured such that the first electrode is formed along one side of the thermoelectric conversion material film, the second electrode is formed along the other side facing the one side of the thermoelectric conversion material film, the first electrode is connected to the second electrode on the thermoelectric conversion material film adjacent to one side, and the second electrode is connected to the first electrode on the thermoelectric conversion material film adjacent to the other side.

Incidentally, the thermoelectric conversion module described in Patent Document 1 described above is configured such that the first electrode and the second electrode of the adjacent thermoelectric conversion material films are connected by wiring drawn around the periphery of the thermoelectric conversion material films. However, in the case of such a configuration, there is a problem in that a sufficient output cannot be obtained because the entire length in which the wiring is drawn is increased and the resistance of the wiring is increased.

### SUMMARY

It is desirable to provide a thermoelectric conversion device capable of improving an output.

The thermoelectric conversion device including:

a base material having a first surface and a second surface facing each other in a thickness direction;

thermoelectric conversion element arrays each having thermoelectric conversion elements lined up in a first direction among the first direction and a second direction intersecting each other in a plane on the first surface side of the base material, the thermoelectric conversion element arrays being disposed in a row in the second direction;

first electrodes, each of which is provided at one end side of each thermoelectric conversion element constituting the thermoelectric conversion element array in the second direction and second electrodes, each of which is provided at other end side of the each thermoelectric conversion element in the second direction;

first wirings, each of which is disposed between one thermoelectric conversion element and other thermoelectric conversion element adjacent in the first direction and electrically connected between the first electrodes or the second electrodes of the one thermoelectric conversion element and the other thermoelectric conversion element such that the thermoelectric conversion elements constituting the thermoelectric conversion element array are connected in series; and

second wirings, each of which is electrically connected between the first electrodes or the second electrodes of the thermoelectric conversion elements located at one-end-most sides or other-end-most sides of one thermoelectric conversion element array and other thermoelectric conversion element array in the first direction such that thermoelectric conversion elements constituting the one thermoelectric conversion element array and thermoelectric conversion elements constituting the other thermoelectric conversion element array adjacent to the one thermoelectric conversion element array in the second direction are connected to each other in series.

### BRIEF DESCRIPTION OF THE DRAWINGS

FIG. 1 is a plan view showing a schematic configuration of a thermoelectric conversion device according to a first embodiment of the disclosure.

FIG. 2 is a cross-sectional view of the thermoelectric conversion device taken along the line A-A shown in FIG. 1.

FIG. 3 is a plan view showing a schematic configuration of a thermoelectric conversion device according to a second embodiment of the disclosure.

FIG. 4 is a cross-sectional view showing a schematic configuration of a thermoelectric conversion device according to a third embodiment of the disclosure.

FIG. 5 is a cross-sectional view showing a schematic configuration of a thermoelectric conversion device according to a fourth embodiment of the disclosure.

### DETAILED DESCRIPTION

Hereinafter, embodiments will be described in detail with appropriate reference to the drawings.

In the drawings used for the following description, there are cases where characteristic parts are shown in an enlarged manner for the sake of convenience so that their characteristics can be easily understood and dimensional ratios of components are not necessarily the same as the actual ratios. Materials or the like provided as exemplary examples in the following description are merely examples and the present invention is not limited thereto and can be carried out by being appropriately modified within a range in which the subject matter of the present invention is not changed.

### First Embodiment

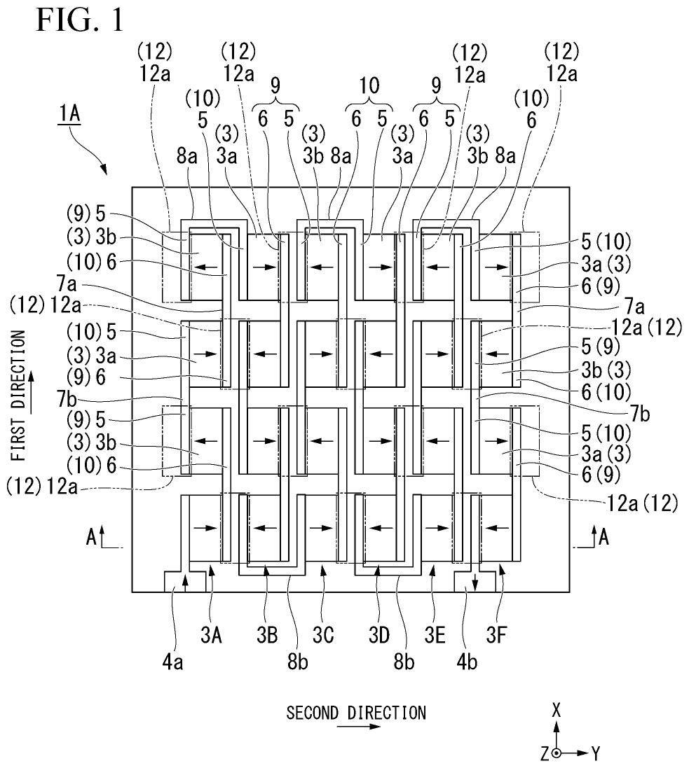

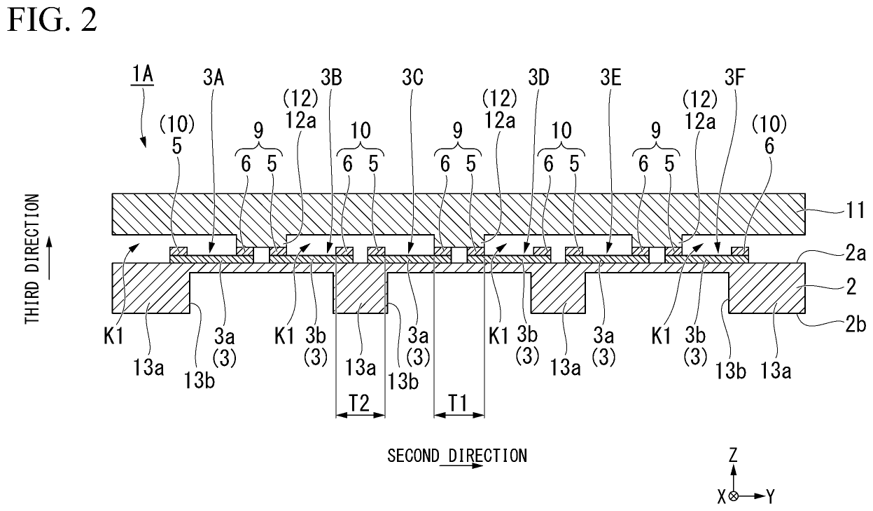

First, for example, a thermoelectric conversion device 1A shown in FIGS. 1 and 2 will be described as a first embodiment of the disclosure. Also, FIG. 1 is a plan view showing a schematic configuration of the thermoelectric conversion device 1A. FIG. 2 is a cross-sectional view of the thermoelectric conversion device 1A taken along the line segment A-A shown in FIG. 1.

Also, in the drawings shown below, it is assumed that an XYZ orthogonal coordinate system is set, an X axis direction is shown as a first direction in a surface of a substrate 2 of the thermoelectric conversion device 1A, a Y axis direction is shown as a second direction in a surface of the substrate 2 of the thermoelectric conversion device 1A, and a Z axis direction is shown as a third direction (a thickness/height direction) orthogonal to the inside of the surface of the substrate 2 of the thermoelectric conversion device 1A.

As shown in FIGS. 1 and 2, the thermoelectric conversion device 1A of the present embodiment has a structure in which a plurality of thermoelectric conversion elements 3 disposed in a row on the surface of the substrate 2 are connected in series between a pair of terminals 4a and 4b.

The substrate 2 is made of an insulating base material having a first surface (an upper surface in the present embodiment) 2a and a second surface (a lower surface in the present embodiment) 2b facing each other in a thickness direction. For example, it is preferable to use a high-resistance silicon (Si) substrate having a substrate resistance of 10Ω or more as the substrate 2.

By setting the substrate resistance to 10Ω or more, it is possible to prevent the occurrence of an electrical short circuit between the plurality of thermoelectric conversion elements 3.

In addition to the above-described high-resistance Si substrate, for example, a silicon on insulator (SOI)) substrate having an oxide insulating layer within the substrate, a ceramic substrate, a high-resistance single crystal substrate, or the like is used as the substrate 2. Furthermore, even if the substrate 2 is a low-resistance substrate having a substrate resistance of 10Ω or less, it is possible to use a configuration in which a high-resistance material is disposed between the low-resistance substrate and the thermoelectric conversion element 3.

The plurality of thermoelectric conversion elements 3 are disposed in a row in a matrix on the first surface 2a of the substrate 2. The plurality of thermoelectric conversion elements 3 include a thermoelectric conversion film which is either an n-type semiconductor or a p-type semiconductor (an n-type semiconductor in the present embodiment). When the thermoelectric conversion element 3 is an n-type thermoelectric conversion film, for example, it is possible to use a multilayer film of an n-type silicon (Si) film and an n-type silicon germanium (SiGe) alloy film doped with antimony (Sb) at a high concentration (from 10¹⁸ to 10¹⁹ cm⁻³). Also, the plurality of thermoelectric conversion elements 3 may be n-type semiconductors having the same configuration as each other or may be n-type semiconductors having different configurations. When the thermoelectric conversion element 3 is an n-type semiconductor, a current flows from a cold junction side to a hot junction side in the thermoelectric conversion element 3.

On the other hand, when the thermoelectric conversion element 3 is a p-type thermoelectric conversion film, for example, it is possible to use a multilayer film of a p-type silicon (Si) film and a p-type silicon germanium (SiGe) alloy film doped with boron (B) at a high concentration (10¹⁸ to 10¹⁹ cm⁻³). Also, the plurality of thermoelectric conversion elements 3 may be p-type semiconductors having the same configuration as each other or may be p-type semiconductors having different configurations. When the thermoelectric conversion element 3 is a p-type semiconductor, a current flows from the hot junction side to the cold junction side in the thermoelectric conversion element 3.

Furthermore, the thermoelectric conversion element 3 is not necessarily limited to the multilayer film of the n-type or p-type semiconductor described above and may be a single-layer film of the n-type or p-type semiconductor. Also, an oxide semiconductor can be used as the semiconductor. Also, for example, a thermoelectric conversion film made of an organic polymer film, a metal film, or the like can be used. Also, the thermoelectric conversion element 3 is not limited to the above-described thermoelectric conversion film and a bulk thermoelectric conversion element may be used.

The thermoelectric conversion device 1A of the present embodiment includes a plurality of thermoelectric conversion element arrays 3A to 3F (six thermoelectric conversion element arrays in the present embodiment) each having a plurality of thermoelectric conversion elements 3 (four thermoelectric conversion elements in the present embodiment) lined up in a first direction between the first direction (the X axis direction) and a second direction (the Y axis direction) intersecting (orthogonal in the present embodiment) each other in a plane on the first surface side 2a of the substrate 2 and disposed in a row in the second direction.

The thermoelectric conversion elements 3 constituting the thermoelectric conversion element arrays 3A to 3F are formed to have the same size and a rectangular shape (a rectangular shape in the present embodiment) in a plan view. Also, the thermoelectric conversion elements 3 are disposed in a row at fixed intervals in the first direction by setting the first direction as a longitudinal direction and setting the second direction as a transverse direction. Furthermore, one thermoelectric conversion element array and the other thermoelectric conversion element array adjacent in the second direction are disposed in parallel to each other with a fixed interval therebetween.

Each of the thermoelectric conversion elements 3 constituting the thermoelectric conversion element arrays 3A to 3F includes a first electrode 5 provided at one end side (a −Y side) of the thermoelectric conversion element 3 in the second direction and a second electrode 6 provided at the other end side (a +Y side) of the thermoelectric conversion element 3 in the second direction. The first electrode 5 and the second electrode 6 are electrically connected to each thermoelectric conversion element 3.

It is preferable to use metals as materials of the first electrode 5 and the second electrode 6, among which it is possible to preferably use, for example, copper (Cu), gold (Au), and the like which have particularly high electrical conductivity and thermal conductivity and facilitate shape processing.

The first electrode 5 and the second electrode 6 are disposed on a top surface of the thermoelectric conversion element 3 along a side surface of one end side and a side surface on the other end side facing in the second direction. Also, the first electrode 5 and the second electrode 6 may be disposed on the first surface 2a of the substrate 2 and may be configured such that the first electrode 5 and the second electrode 6 are in contact with the side surface of the one end side and the side surface of the other end side of the thermoelectric conversion element 3 facing in the second direction.

The first electrode 5 and the second electrode 6 are formed to have the same size and a rectangular shape (a rectangular shape in the present embodiment) in a plan view across the entire region of the thermoelectric conversion element 3 in the longitudinal direction (the first direction). Also, the first electrode 5 (or the second electrode 6) of the one thermoelectric conversion element 3 and the second electrode 6 (or the first electrode 5) of the other thermoelectric conversion element 3 are disposed in a state in which they are separated from each other between one thermoelectric conversion element 3 and the other thermoelectric conversion element 3 adjacent to each other in the second direction.

The thermoelectric conversion device 1A includes a thermoelectric conversion element 3 (hereinafter referred to as a “first thermoelectric conversion element 3a” as necessary) in which the current flows from the first electrode 5 side to the second electrode 6 side and a thermoelectric conversion element 3 (hereinafter referred to as a “second thermoelectric conversion element 3b” as necessary) in which the current flows from the second electrode 6 side to the first electrode 5 side in the plurality of thermoelectric conversion elements 3.

Also, in FIG. 1, a direction of a current that flows through the first thermoelectric conversion element 3a, a direction of a current that flows through the second thermoelectric conversion element 3b, a direction of a current that flows through one terminal 4a, and a direction of a current that flows through the other terminal 4b are indicated by the directions of arrows.

The plurality of thermoelectric conversion element arrays 3A to 3F have a configuration in which the thermoelectric conversion elements 3 having opposite current flow directions between the first electrode 5 and the second electrode 6 are alternately disposed in a row in the first direction. That is, in the thermoelectric conversion element arrays 3A to 3F, the first thermoelectric conversion elements 3a and the second thermoelectric conversion elements 3b are alternately disposed in a row in the first direction.

Also, the thermoelectric conversion device 1A has a configuration in which the thermoelectric conversion elements 3 having opposite current flow directions between the first electrode 5 and the second electrode 6 are alternately disposed in a row in the second direction. That is, in the thermoelectric conversion device 1A, the first thermoelectric conversion elements 3a and the second thermoelectric conversion elements 3b are alternately disposed in a row in the second direction.

In the thermoelectric conversion device 1A of the present embodiment, in the thermoelectric conversion element arrays 3A, 3C, and 3E, the first thermoelectric conversion elements 3a and the second thermoelectric conversion elements 3b are alternately disposed in a row from one end side to the other end side in the first direction. On the other hand, in the thermoelectric conversion element arrays 3B, 3D, and 3F, the second thermoelectric conversion elements 3b and the first thermoelectric conversion elements 3a are alternately disposed in a row from one end side to the other end side in the first direction.

Therefore, in the thermoelectric conversion device 1A of the present embodiment, the first thermoelectric conversion elements 3a and the second thermoelectric conversion elements 3b are alternately disposed in a row in the first direction and the second direction in the plane on the first surface 2a side of the substrate 2.

A pair of terminals 4a and 4b are disposed on the first surface 2a of the substrate 2. Also, materials which are the same as the above-described examples of the materials of the first electrode 5 and the second electrode 6 can be used as the materials of the pair of terminals 4a and 4b.

One terminal 4a of the pair of terminals 4a and 4b is electrically connected to the first electrode 5 of the thermoelectric conversion element 3 (the first thermoelectric conversion element 3a) located at a one-end-most side (the −X side) in the first direction in the thermoelectric conversion elements 3 constituting the thermoelectric conversion element array 3A located at a one-end-most side (the −Y side) in the second direction. That is, one terminal 4a is continuous with the first electrode 5 in the longitudinal direction (the first direction) and is formed at a position where a protrusion is formed (toward the −X side) outside the first electrode 5 in a rectangular shape (a rectangular shape in the present embodiment) in a plan view.

On the other hand, the other terminal 4b is electrically connected to the first electrode 5 of the thermoelectric conversion element 3 (the second thermoelectric conversion element 3b) located at a one-end-most side (the −X side) in the first direction in the thermoelectric conversion elements 3 constituting the thermoelectric conversion element array 3F located at the other-end-most side (the +Y side) in the second direction. That is, the other terminal 4b is continuous with the first electrode 5 in the longitudinal direction (the first direction) and is formed at a position where a protrusion is formed (toward the −X side) outside the first electrode 5 in a rectangular shape (a rectangular shape in the present embodiment) in a plan view.

The thermoelectric conversion device 1A of the present embodiment includes a plurality of first wirings 7a and 7b connected to each other in series between the plurality of thermoelectric conversion elements 3 constituting each of the thermoelectric conversion element arrays 3A to 3F; and a plurality of second wirings 8a and 8b connected to each other in series between the plurality of thermoelectric conversion element arrays 3A to 3F such that they are connected to each other in series between a plurality of thermoelectric conversion elements 3 constituting one thermoelectric conversion element array adjacent in the second direction in the plurality of thermoelectric conversion element arrays 3A to 3F and a plurality of thermoelectric conversion elements 3 constituting the other thermoelectric conversion element array.

The plurality of first wirings 7a and 7b and the plurality of second wirings 8a and 8b are disposed on the first surface 2a of the substrate 2 and formed such that they are continuous with the first electrode 5 or the second electrode 6 electrically connected thereto. Therefore, materials which are the same as the above-described examples of the materials of the first electrode 5 and the second electrode 6 can be used as materials of the first wirings 7a and 7b and the second wirings 8a and 8b.

The first wirings 7a and 7b are disposed between one thermoelectric conversion element and the other thermoelectric conversion element adjacent in the first direction in the plurality of thermoelectric conversion elements 3 constituting each of the thermoelectric conversion element arrays 3A to 3F. The first wirings 7a and 7b are electrically connected between the first electrodes 5 or the second electrodes 6 of the one thermoelectric conversion element 3 and the other thermoelectric conversion element 3.

Specifically, the second electrode (hereinafter referred to as “one second electrode”) 6 of the thermoelectric conversion element 3 located at a (2n−1)^{th} position (n denotes a natural number) from one end side (the −X side) in the first direction in the thermoelectric conversion elements 3 constituting each of the thermoelectric conversion element arrays 3A to 3F and the second electrode (hereinafter referred to as the “other second electrode”) 6 of the thermoelectric conversion element 3 located at a 2n^{th} position from the one end side (the −X side) in the first direction are electrically connected via the first wiring 7a having a straight line shape lined up on the identical straight line as the second electrodes 6. (In the present embodiment, n=1 to 2.)

The first wiring 7a is formed in a row in a straight line shape on the identical straight line as the second electrodes 6 while being continuous with the other end of one second electrode 6 in the longitudinal direction (the first direction) and one end of the other second electrode 6 in the longitudinal direction (the first direction) and therefore the first wiring 7a is drawn between the one second electrode 6 and the other second electrode 6. That is, the one second electrode 6, the other second electrode 6, and the first wiring 7a are formed in a row on a straight line.

Also, the first electrode (hereinafter referred to as “one first electrode”) 5 of the thermoelectric conversion element 3 located at a 2n^{th} position (n denotes a natural number) from one end side (the −X side) in the first direction in the thermoelectric conversion elements 3 constituting each of the thermoelectric conversion element arrays 3A to 3F and the first electrode 5 (hereinafter referred to as the “other first electrode”) 5 of the thermoelectric conversion element 3 located at a (2n+1)^{th} position from the one end side (the −X side) in the first direction are electrically connected via the first wiring 7b having a straight line shape lined up on the identical straight line as the first electrodes 5. (In the present embodiment, n=1.)

The first wiring 7b is formed in a row in a straight line shape on the identical straight line as the first electrodes 5 while being continuous with the other end of one first electrode 5 in the longitudinal direction (the first direction) and one end of the other first electrode 5 in the longitudinal direction (the first direction) and therefore the first wiring 7b is drawn between the one first electrode 5 and the other first electrode 5. That is, the one first electrode 5, the other first electrode 5, and the first wiring 7b are formed in a row on a straight line.

The second wirings 8a and 8b are disposed outside (on the −X side or the +X side) of the thermoelectric conversion elements 3 located at one-end-most sides or the other-end-most sides of the first direction of one thermoelectric conversion element array and the other thermoelectric conversion element array adjacent in the second direction in the plurality of thermoelectric conversion element arrays 3A to 3F. The second wirings 8a and 8b are electrically connected between the first electrodes 5 or the second electrodes 6 of the thermoelectric conversion elements 3 located at one-end-most sides or the other-end-most sides of one thermoelectric conversion element array and the other thermoelectric conversion element array in the first direction.

Specifically, the first electrode 5 of the thermoelectric conversion element 3 located at the other-end-most side (the +X side) of the first direction of the thermoelectric conversion element arrays 3A, 3C, and 3E located at a (2m−1) position (m denotes a natural number) from one end side (the −Y side) in the second direction in the plurality of thermoelectric conversion element arrays 3A to 3F and the first electrode 5 of the thermoelectric conversion element 3 located at the other-end-most side (the +X side) of the first direction of the thermoelectric conversion element arrays 3B, 3D, and 3F located at a 2m^{th} position from one end side (the −Y side) in the second direction are electrically connected via the second wiring 8a having a bent shape. (In the present embodiment, m=1 to 3.)

The second wiring 8a is bent at a position where a protrusion is formed (toward the +X side) outside each first electrode 5 while being continuous with the other ends of the first electrodes 5 in the longitudinal direction (the first direction) and is formed in a straight line shape in a direction (the second direction) orthogonal to the first direction therebetween and therefore the second wiring 8a is drawn between the first electrodes 5.

Also, the first electrode 5 of the thermoelectric conversion element 3 located at a one-end-most side (the −X side) of the first direction of the thermoelectric conversion element arrays 3B and 3D located at a 2m^{th} position (m denotes a natural number) from one end side (the −Y side) in the second direction in the plurality of thermoelectric conversion element arrays 3A to 3F and the first electrode 5 of the thermoelectric conversion element 3 located at a one-end-most side (the −X side) of the first direction of the thermoelectric conversion element arrays 3C and 3E located at a (2m+1)^{th} position from one end side (the −Y side) in the second direction are electrically connected via the second wiring 8b having a bent shape. (In the present embodiment, m=1 to 2.)

The second wiring 8b is bent at a position where a protrusion is formed (toward the −X side) outside each first electrode 5 while being continuous with one ends of the first electrodes 5 in the longitudinal direction (the first direction) and is formed in a straight line shape in a direction (the second direction) orthogonal to the first direction therebetween and therefore the second wiring 8b is drawn between the first electrodes 5.

Thereby, in the thermoelectric conversion device 1A of the present embodiment, the plurality of thermoelectric conversion elements 3 constituting each of the thermoelectric conversion element arrays 3A to 3F are connected in series to each other via the plurality of first wirings 7a and 7b. Also, the plurality of thermoelectric conversion element arrays 3A to 3F are connected to each other in series via the plurality of second wirings 8a and 8b such that the plurality of thermoelectric conversion elements 3 constituting one thermoelectric conversion element array adjacent in the second direction in the plurality of thermoelectric conversion element arrays 3A to 3F and the plurality of thermoelectric conversion elements 3 constituting the other thermoelectric conversion element array are connected to each other in series.

Each of the thermoelectric conversion elements 3 constituting the thermoelectric conversion element arrays 3A to 3F includes the first electrode 5 or the second electrode 6 located at a hot junction side (hereinafter collectively referred to as a “hot junction side electrodes 9”) and has the second electrode 6 or the first electrode 5 located at a cold junction side (hereinafter collectively referred to as a “cold junction side electrode 10”).

Hot junction side electrodes 9 include the second electrode 6 of the first thermoelectric conversion element 3a and the first electrode 5 of the second thermoelectric conversion element 3b. On the other hand, cold junction side electrodes 10 include the first electrode 5 of the first thermoelectric conversion element 3a and the second electrode 6 of the second thermoelectric conversion element 3b. Therefore, the hot junction side electrodes 9 and the cold junction side electrodes 10 are alternately disposed in a row in the first direction, and alternately disposed in a row in the second direction. That is, the hot junction side electrodes 9 and the cold junction side electrodes 10 are alternately disposed in a row in the first direction and the second direction.

The hot junction side electrodes 9 include the first electrode 5 and the second electrode 6 adjacent in the second direction. Also, the cold junction side electrodes 10 include the first electrode 5 and the second electrode 6 adjacent in the second direction.

Here, each of the first electrode 5 of the second thermoelectric conversion element 3b located at a one-end-most side (the −Y side) in the second direction and the second electrode 6 of the first thermoelectric conversion element 3a located at the other-end-most side (the +Y side) in the second direction independently constitutes the hot junction side electrode 9.

Also, each of the first electrode 5 of the first thermoelectric conversion element 3a located at a one-end-most side (the −Y side) in the second direction and the second electrode 6 of the second thermoelectric conversion element 3b located at the other-end-most side (the +Y side) in the second direction constitutes the cold junction side electrode 10.

The thermoelectric conversion device 1A of the present embodiment includes a first heat transfer plate 11 disposed on the first surface 2a side of the substrate 2 as a first heat transfer member of a high-temperature (heating) side. The first heat transfer plate 11 is made of a material having higher thermal conductivity than air, preferably, a material having higher thermal conductivity than the substrate 2. It is preferable to use metals as a material of such a first heat transfer plate 11. Among the metals, particularly, for example, aluminum (Al), copper (Cu), and the like in which thermal conductivity is high and shape processing is facilitated can be preferably used. Also, the first heat transfer plate 11 may be made of a plurality of heat transfer members.

The first heat transfer plate 11 is thermally connected with the hot junction side electrode 9 via the heat transfer part 12. The heat transfer part 12 has a protrusion 12a protruding from a surface side of one of surfaces facing the first heat transfer plate 11 and the hot junction side electrode 9.

In the present embodiment, the protrusion 12a protruding from the first heat transfer plate 11 side constitutes the heat transfer part 12. Because the protrusion 12a is integrally formed with the first heat transfer plate 11, materials which are the same as the above-described examples of the material of the first heat transfer plate 11 may be used as the material of the protrusion 12a (the heat transfer part 12).

The heat transfer part 12 of the present embodiment has a plurality of protrusions 12a protruding from a position facing each hot junction side electrode 9 of the first heat transfer plate 11 to the substrate 2 side (a −Z side). Each protrusion 12a has a rectangular shape (a cross-sectional rectangular shape in the present embodiment) in a plan view and is provided such that the protrusion 12a protrudes in a range T1 overlapping the first electrode 5 and the second electrode 6 that constitute the hot junction side electrodes 9.

Further, the tips of the protrusions 12a are thermally connected in a state in which they are electrically insulated from the hot junction side electrodes 9 via, for example, an insulating connecting material (not shown). The connecting material is made of an insulating material having higher thermal conductivity than air. As a material of such a connecting material, for example, a UV curable resin, a silicone resin, a thermal conductive grease (for example, a silicone grease, a non-silicone grease containing a metal oxide, and the like), and the like can be used.

Also, when the heat transfer part 12 is electrically insulated from the hot junction side electrode 9 by the insulating layer or the like provided at the tip of the protrusion 12a described above or when electrical insulation between the tip of the protrusion 12a and the hot junction side electrode 9 is not problematic, the heat transfer part 12 may directly connect with the hot junction side electrode 9 without involving the above-described insulating junction material.

Also, the heat transfer part 12 is not limited to a case in which the heat transfer part 12 includes the protrusion 12a protruding from the above-described first heat transfer plate 11 side and can include the protrusion 12a protruding from the hot junction side electrode 9 side. In this case, because the protrusion 12a is integrally formed with the hot junction side electrode 9 (the first electrode 5 and the second electrode 6), materials which are the same as the above-described examples of the materials of the first electrode 5 and the second electrode 6 can be used as a material of the protrusion 12a (the heat transfer part 12).

Furthermore, it is also possible to provide another heat transfer member (including the above-described connecting material) for thermally forming a connection between the first heat transfer plate 11 and the hot junction side electrode 9 as the heat transfer part 12. For example, the first heat transfer plate 11 and the hot junction side electrode 9 can be configured to thermally connect via the above-described connecting material configured to be the heat transfer part 12 without involving the above-described protrusion 12a by making the thickness of the hot junction side electrode 9 greater than the thickness of the cold junction side electrode 10.

Also, the first heat transfer plate 11 and the hot junction side electrode 9 are not limited to a configuration in which the first heat transfer plate 11 and the hot junction side electrode 9 are thermally connected via the above-described heat transfer part 12. When the first heat transfer plate 11 and the hot junction side electrode 9 are electrically insulated by an insulating layer or the like provided on the surface of the first heat transfer plate 11 or when electrical insulation between the first heat transfer plate 11 and the hot junction side electrode 9 is not problematic, a configuration in which the first heat transfer plate 11 and the hot junction side electrode 9 are directly connected without involving the above-described insulating connecting material is possible.

Also, in the thermoelectric conversion device 1A of the present embodiment, a space K1 is provided between the first surface 2a side of the substrate 2 and the first heat transfer plate 11 by forming a connection between the first heat transfer plate 11 and the hot junction side electrode 9 described above via the heat transfer part 12 (the protrusion 12a).

Also, in the thermoelectric conversion device 1A of the present embodiment, it is also possible to fill the above-described space K1 with a heat insulation material made of a material having lower thermal conductivity than the heat transfer part 12. That is, the heat transfer part 12 forms a part having relatively higher thermal conductivity than the surroundings (the space K1 and the heat insulation material) thereof between the first heat transfer plate 11 and the hot junction side electrode 9.

In the thermoelectric conversion device 1A of the present embodiment, the substrate 2 has a configuration in which a thickness of at least a part facing the cold junction side electrode 10 is greater than a thickness of at least a part facing the hot junction side electrode 9.

Specifically, while the first surface 2a of the substrate 2 is a flat surface, the second surface 2b of the substrate 2 has a plurality of protrusions 13a (four protrusions 13a in the present embodiment) and a plurality of recesses 13b (three recesses 13b in the present embodiment) alternately lined up and provided in the second direction.

The plurality of protrusions 13a include a range T2 overlapping each cold junction side electrode 10 in a plan view and are provided to protrude with a fixed height. The plurality of recesses 13b are provided to be recessed with a fixed depth across spaces between the plurality of protrusions 13a. Thereby, the thickness of a part in which the protrusion 13a of the substrate 2 is provided is greater than the thickness of a part in which the recess 13b is provided. Also, the protrusions 13a located at both ends in the second direction are provided such that the protrusions 13a are extended to both ends of the second surface 2b with a fixed height in the second direction.

In the thermoelectric conversion device 1A having the above-described configuration, the first heat transfer plate 11 is disposed on a high-temperature (heating) side and the second surface 2b of the substrate 2 is disposed on a low-temperature (heat radiation/cooling) side. Thereby, the temperature of the hot junction side electrode 9 side of each thermoelectric conversion element 3 is relatively high due to the heat transferred from the first heat transfer plate 11 to the hot junction side electrode 9 via the protrusion 12a (the heat transfer part 12). On the other hand, because the heat transferred to each thermoelectric conversion element 3 is externally radiated from the cold junction side electrode 10 via the protrusion 13a of the substrate 2, the cold junction side electrode 10 side of each thermoelectric conversion element 3 has a relatively low temperature. Therefore, a temperature difference occurs between the hot junction side electrode 9 and the cold junction side electrode 10 of each thermoelectric conversion element 3.

Thereby, movement of charges (carriers) occurs between the first electrode 5 and the second electrode 6 of each thermoelectric conversion element 3. That is, an electromotive force (voltage) is generated due to a Seebeck effect between the first electrode 5 and the second electrode 6 of each thermoelectric conversion element 3 and a current flows from the cold junction side electrode 10 to the hot junction side electrode 9 in each thermoelectric conversion element 3.

Although an electromotive force (a voltage) generated by one thermoelectric conversion element 3 is low, a plurality of thermoelectric conversion elements 3 are connected in series between one terminal 4a and the other terminal 4b. Therefore, it is possible to extract a relatively high voltage between the one terminal 4a and the other terminal 4b as a total of electromotive force. Also, a current can flow from one terminal 4a side to the other terminal 4b side.

In the thermoelectric conversion device 1A of the present embodiment, a plurality of first wirings 7a and 7b connected to each other in series between the plurality of thermoelectric conversion elements 3 constituting the above-described thermoelectric conversion element arrays 3A to 3F and a plurality of second wirings 8a and 8b connected to each other in series between the plurality of thermoelectric conversion element arrays 3A to 3F such that a plurality of thermoelectric conversion elements 3 constituting one thermoelectric conversion element array adjacent in the second direction in the plurality of thermoelectric conversion element arrays 3A to 3F and a plurality of thermoelectric conversion elements 3 constituting the other thermoelectric conversion element array are connected to each other in series are drawn between the pair of terminals 4a and 4b.

Thereby, in the thermoelectric conversion device 1A of the present embodiment, it is possible to shorten the total length of the wirings 7a, 7b, 8a, and 8b drawn to connect the plurality of thermoelectric conversion elements 3 in series between the pair of terminals 4a and 4b as compared with the conventional technology and reduce the total resistance of the wirings 7a, 7b, 8a, and 8b.

Therefore, in the thermoelectric conversion device 1A of the present embodiment, it is possible to suppress the loss when the current generated in each thermoelectric conversion element 3 flows through the wirings 7a, 7b, 8a, and 8b and consequently improve output (power).

### Second Embodiment

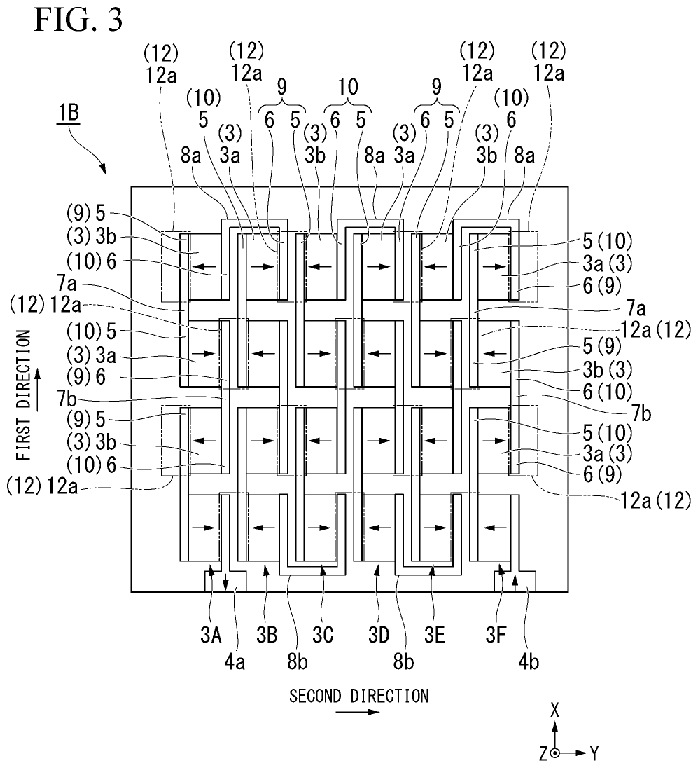

Next, for example, a thermoelectric conversion device 1B shown in FIG. 3 will be described as a second embodiment of the disclosure. FIG. 3 is a plan view showing a schematic configuration of the thermoelectric conversion device 1B. Also, a description of parts equivalent to those of the above-described thermoelectric conversion device 1A will be omitted in the following description and the equivalent parts will be denoted by the same reference signs in the drawings.

As shown in FIG. 3, the thermoelectric conversion device 1B of the present embodiment basically has the same configuration as the above-described thermoelectric conversion device 1A, except for a difference from the above-described thermoelectric conversion device 1A in terms of the arrangement of first wirings 7a and 7b and second wirings 8a and 8b drawn between the above-described pair of terminals 4a and 4b.

Also, in FIG. 3, a direction of a current that flows through the first thermoelectric conversion element 3a, a direction of a current that flows through the second thermoelectric conversion element 3b, a direction of a current that flows through one terminal 4a, and a direction of a current that flows through the other terminal 4b are indicated by the directions of arrows.

Specifically, a first electrode (hereinafter referred to as “one first electrode”) 5 of a thermoelectric conversion element 3 located at a (2n−1)^{th} position (n denotes a natural number) from one end side (a −X side) in a first direction in thermoelectric conversion elements 3 constituting each of thermoelectric conversion element arrays 3A to 3F and a first electrode (hereinafter referred to as the “other first electrode”) 5 of a thermoelectric conversion element 3 located at a 2n^{th} position from the one end side (the −X side) in the first direction are electrically connected via a first wiring 7a having a straight line shape lined up on the identical straight line as the first electrodes 5. (In the present embodiment, n=1 to 2.)

The first wiring 7a is formed in a row in a straight line shape on the identical straight line as the first electrodes 5 while being continuous with the other end of one first electrode 5 in the longitudinal direction (the first direction) and one end of the other first electrode 5 in the longitudinal direction (the first direction) and therefore the first wiring 7a is drawn between the one first electrode 5 and the other first electrode 5. That is, the one first electrode 5, the other first electrode 5, and the first wiring 7a are formed in a row on a straight line.

Also, a second electrode (hereinafter referred to as “one second electrode”) 6 of the thermoelectric conversion element 3 located at a 2n^{th} position (n denotes a natural number) from one end side (the −X side) in the first direction in the thermoelectric conversion elements 3 constituting each of the thermoelectric conversion element arrays 3A to 3F and a second electrode (hereinafter referred to as the “other second electrode”) 6 of the thermoelectric conversion element 3 located at a (2n+1)^{th} position from the one end side (the −X side) in the first direction are electrically connected via the first wiring 7b having a straight line shape lined up on the identical straight line as the second electrodes 6. (In the present embodiment, n=1.)

The first wiring 7b is formed in a row in a straight line shape on the identical straight line as the second electrodes 6 while being continuous with the other end of one second electrode 6 in the longitudinal direction (the first direction) and one end of the other second electrode 6 in the longitudinal direction (the first direction) and therefore the first wiring 7b is drawn between the one second electrode 6 and the other second electrode 6. That is, the one second electrode 6, the other second electrode 6, and the first wiring 7b are formed in a row on a straight line.

Also, the second electrode 6 of the thermoelectric conversion element 3 located at the other-end-most side (the +X side) of the first direction of the thermoelectric conversion element arrays 3A, 3C, and 3E located at a (2m−1)^{th} position (m denotes a natural number) from one end side (the −Y side) in the second direction in the plurality of thermoelectric conversion element arrays 3A to 3F and the second electrode 6 of the thermoelectric conversion element 3 located at the other-end-most side (the +X side) of the first direction of the thermoelectric conversion element arrays 3B, 3D, and 3F located at a 2m^{th} position from one end side (the −Y side) in the second direction are electrically connected via the second wiring 8a having a bent shape. (In the present embodiment, m=1 to 3.)

The second wiring 8a is bent at a position where a protrusion is formed (toward the +X side) outside each second electrode 6 while being continuous with the other ends of the second electrodes 6 in the longitudinal direction (the first direction) and is formed in a straight line shape in a direction (the second direction) orthogonal to the first direction therebetween and therefore the second wiring 8a is drawn between the second electrodes 6.

Also, the second electrode 6 of the thermoelectric conversion element 3 located at a one-end-most side (the −X side) of the first direction of the thermoelectric conversion element arrays 3B and 3D located at a 2m^{th} position (m denotes a natural number) from one end side (the −Y side) in the second direction in the plurality of thermoelectric conversion element arrays 3A to 3F and the second electrode 6 of the thermoelectric conversion element 3 located at a one-end-most side (the −X side) of the first direction of the thermoelectric conversion element arrays 3C and 3E located at a (2m+1)^{th} position from one end side (the −Y side) in the second direction are electrically connected via the second wiring 8b having a bent shape. (In the present embodiment, m=1 to 2.)

The second wiring 8b is bent at a position where a protrusion is formed (toward the −X side) outside each second electrode 6 while being continuous with one ends of the second electrodes 6 in the longitudinal direction (the first direction) and is formed in a straight line shape in a direction (the second direction) orthogonal to the first direction therebetween and therefore the second wiring 8b is drawn between the second electrodes 6.

Thereby, in the thermoelectric conversion device 1B of the present embodiment, the plurality of thermoelectric conversion elements 3 constituting each of the thermoelectric conversion element arrays 3A to 3F are connected in series to each other via the plurality of first wirings 7a and 7b. Also, the plurality of thermoelectric conversion element arrays 3A to 3F are connected to each other in series via the plurality of second wirings 8a and 8b such that the plurality of thermoelectric conversion elements 3 constituting one thermoelectric conversion element array adjacent in the second direction in the plurality of thermoelectric conversion element arrays 3A to 3F and the plurality of thermoelectric conversion elements 3 constituting the other thermoelectric conversion element array are connected to each other in series.

Also, one terminal 4a of the pair of terminals 4a and 4b is electrically connected to the second electrode 6 of the thermoelectric conversion element 3 (the first thermoelectric conversion element 3a) located at a one-end-most side (the −X side) in the first direction in the thermoelectric conversion elements 3 constituting the thermoelectric conversion element array 3A located at a one-end-most side (the −Y side) in the second direction. That is, one terminal 4a is formed at a position where a protrusion is formed (toward the −X side) outside the second electrode 6 in a rectangular shape (a rectangular shape in the present embodiment) in a plan view while being continuous with the second electrode 6 in the longitudinal direction (the first direction).

On the other hand, the other terminal 4b is electrically connected to the second electrode 6 of the thermoelectric conversion element 3 (the second thermoelectric conversion element 3b) located at a one-end-most side (the −X side) in the first direction in the thermoelectric conversion elements 3 constituting the thermoelectric conversion element array 3F located at the other-end-most side (the +Y side) in the second direction. That is, the other terminal 4b is formed at a position where a protrusion is formed (toward the −X side) outside the second electrode 6 in a rectangular shape (a rectangular shape in the present embodiment) in a plan view while being continuous with the second electrode 6 in the longitudinal direction (the first direction).

Thereby, in the thermoelectric conversion device 1B of the present embodiment, a current can flow from the other terminal 4b side to the one terminal 4a side in contrast to the above-described thermoelectric conversion device 1A.

In the thermoelectric conversion device 1B of the present embodiment, a plurality of first wirings 7a and 7b connected to each other in series between the plurality of thermoelectric conversion elements 3 constituting the above-described thermoelectric conversion element arrays 3A to 3F and a plurality of second wirings 8a and 8b connected to each other in series between the plurality of thermoelectric conversion element arrays 3A to 3F are drawn between the pair of terminals 4a and 4b such that a plurality of thermoelectric conversion elements 3 constituting one thermoelectric conversion element array adjacent in the second direction in the plurality of thermoelectric conversion element arrays 3A to 3F and a plurality of thermoelectric conversion elements 3 constituting the other thermoelectric conversion element array are connected to each other in series.

Thereby, in the thermoelectric conversion device 1B of the present embodiment, it is possible to shorten the total length of the wirings 7a, 7b, 8a, and 8b drawn to connect the plurality of thermoelectric conversion elements 3 in series between the pair of terminals 4a and 4b as compared with the conventional technology and reduce the total resistance of the wirings 7a, 7b, 8a, and 8b.

Therefore, in the thermoelectric conversion device 1B of the present embodiment, as in the thermoelectric conversion device 1A, it is possible to suppress the loss when the current generated in each thermoelectric conversion element 3 flows through the wirings 7a, 7b, 8a, and 8b and consequently improve an output (power).

### Third Embodiment

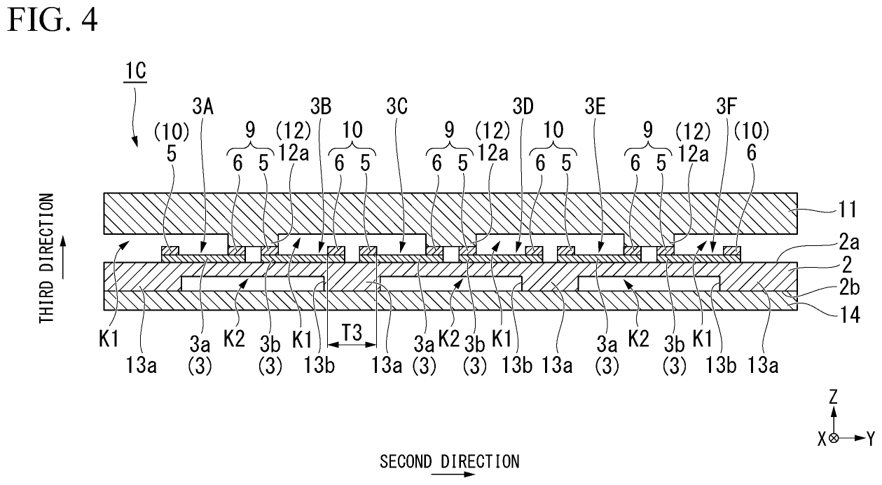

Next, for example, a thermoelectric conversion device 1C shown in FIG. 4 will be described as a third embodiment of the disclosure. Also, FIG. 4 is a cross-sectional view showing a schematic configuration of the thermoelectric conversion device 1C. Also, FIG. 4 is a cross-sectional view of the thermoelectric conversion device 1C corresponding to the line segment A-A shown in FIG. 1. Also, a description of parts equivalent to those of the above-described thermoelectric conversion device 1A will be omitted in the following description and the equivalent parts will be denoted by the same reference signs in the drawings.

As shown in FIG. 4, the thermoelectric conversion device 1C of the present embodiment basically has the same configuration as the above-described thermoelectric conversion device 1A, except that there is provided a second heat transfer plate 14 disposed on a second surface 2b side of the above-described substrate 2 and thermally connected with the substrate 2.

Specifically, the thermoelectric conversion device 1C of the present embodiment has a structure in which the substrate 2 on which a plurality of thermoelectric conversion elements 3 are disposed is sandwiched between a first heat transfer plate 11 configured to be a high-temperature (heating) side and a second heat transfer plate 14 configured to be a low-temperature (heat radiation/cooling) side.

The second heat transfer plate 14 is disposed on the second surface 2b side of the substrate 2 as a second heat transfer member of a low-temperature (heat radiation/cooling) side. The second heat transfer plate 14 is made of a material having higher thermal conductivity than air, preferably a material having higher thermal conductivity than the substrate 2. Materials which are the same as the above-described examples of the material of the first heat transfer plate 11 may be used as a material of such a second heat transfer plate 14. Also, the second heat transfer plate 14 may be made of a plurality of heat transfer members.

The second heat transfer plate 14 is formed in a parallel flat plate shape and is thermally connected with the substrate 2 by abutting on a plurality of protrusions 13a configured to be a heat transfer part. Thereby, the second heat transfer plate 14 is thermally connected with the substrate 2 via the protrusions 13a in a range T3 overlapping the cold junction side electrode 10 in a thickness direction. Also, a space K2 is provided between the second surface 2b of the substrate 2 and the second heat transfer plate 14.

In the thermoelectric conversion device 1C of the present embodiment, the first heat transfer plate 11 is disposed on a high-temperature (heating) side and the second heat transfer plate 14 is disposed on a low-temperature (heat radiation/cooling) side. Thereby, the temperature of the hot junction side electrode 9 side of each thermoelectric conversion element 3 is relatively high due to the heat transferred from the first heat transfer plate 11 to the hot junction side electrode 9 via the heat transfer part 12 (the protrusion 12a). On the other hand, because the heat transferred to each thermoelectric conversion element 3 is externally radiated from the cold junction side electrode 10 via the substrate 2 and the second heat transfer plate 14, the cold junction side electrode 10 side of each thermoelectric conversion element 3 has a relatively low temperature. Therefore, it is possible to cause a temperature difference to occur between the hot junction side electrode 9 and the cold junction side electrode 10 of each thermoelectric conversion element 3.

Also, a configuration in which the second heat transfer plate 14 shown in FIG. 4 is added in addition to the configuration shown in the above-described thermoelectric conversion device 1A is an exemplary example of the thermoelectric conversion device 1C of the present embodiment. Likewise, a configuration in which the second heat transfer plate 14 shown in FIG. 4 is also added to the configuration shown in the above-described thermoelectric conversion device 1B is possible.

### Fourth Embodiment

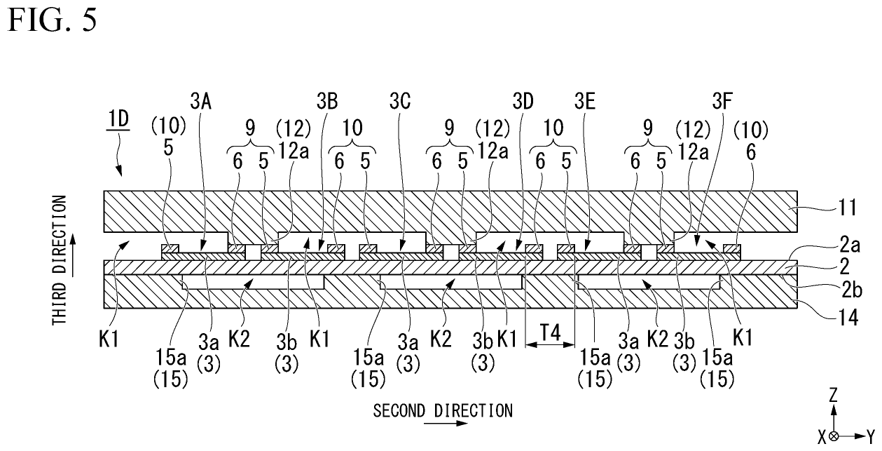

Next, for example, a thermoelectric conversion device 1D shown in FIG. 5 will be described as a fourth embodiment of the disclosure. Also, FIG. 5 is a cross-sectional view showing a schematic configuration of the thermoelectric conversion device 1D. Also, FIG. 5 is a cross-sectional view of the thermoelectric conversion device 1D corresponding to the line segment A-A shown in FIG. 1. Also, a description of parts equivalent to those of the above-described thermoelectric conversion device 1A will be omitted in the following description and equivalent parts will be denoted by the same reference signs in the drawings.

As shown in FIG. 5, the thermoelectric conversion device 1D of the present embodiment basically has the same configuration as the above-described thermoelectric conversion device 1A, except for a configuration in which a second surface 2b of the above-described substrate 2 is a flat surface and a second heat transfer plate 14 disposed on the second surface 2b is thermally connected with the substrate 2 via a heat transfer part 15.

Specifically, the heat transfer part 15 has a plurality of protrusions 15a protruding from a position facing each cold junction side electrode 10 of the second heat transfer plate 14 to the substrate 2 side (a +Z side). Because the protrusion 15a is integrally formed with the second heat transfer plate 14, materials which are the same as the above-described examples of the material of the second heat transfer plate 14 (the first heat transfer plate 11) may be used as a material of the protrusion 15a (the heat transfer part 15).

Each protrusion 15a has a rectangular shape (a cross-sectional rectangular shape in the present embodiment) in a plan view and is provided such that the protrusion 15a protrudes in a range T4 overlapping the first electrode 5 and the second electrode 6 that constitute the cold junction side electrodes 10. Thereby, the second heat transfer plate 14 is thermally connected with the substrate 2 via the protrusions 15a (the heat transfer part 15) in the range T4 overlapping the cold junction side electrode 10 in a thickness direction. Also, a space K2 is provided between the second surface 2b of the substrate 2 and the second heat transfer plate 14.

Also, in the present embodiment, it is also possible to fill the above-described space K2 with a heat insulation material made of a material having lower thermal conductivity than the heat transfer part 15. That is, the heat transfer part 15 forms a part having relatively higher thermal conductivity than the surroundings (the space K2 and the heat insulation material) thereof between the second surface 2b of the substrate 2 and the second heat transfer plate 14.

Also, the second heat transfer plate 14 may have a shape suitable for heat radiation or cooling, in addition to the above-described configuration. For example, in order to air-cool the second heat transfer plate 14, heat radiation fins (heat sinks) may be provided on a surface of the second heat transfer plate 14 opposite the substrate 2. Also, in order to water-cool the second heat transfer plate 14, a flow path along which a coolant flows inside the second heat transfer plate 14 may be provided. In addition to the above-described configuration, it is also possible to provide another heat transfer member for thermally forming a connection between the substrate 2 and the second heat transfer plate 14 with respect to the heat transfer part 15.

Also, although an example of a configuration in which the second heat transfer plate 14 and the heat transfer part 15 shown in FIG. 5 are added in addition to a change in the configuration shown in the above-described thermoelectric conversion device 1A is shown in the thermoelectric conversion device 1D of the present embodiment, a configuration in which the second heat transfer plate 14 and the heat transfer part 15 shown in FIG. 5 are added by adding a similar change to the configuration shown in the thermoelectric conversion device 1B is also possible.

Also, the present invention is not necessarily limited to details of the above-described embodiments and various changes can be added without departing from the scope of the disclosure. For example, a case in which the thermoelectric conversion element 3 made of the above-described n-type semiconductor is used is an exemplary example of the above-described embodiment. However, in contrast, a direction (a direction of an arrow) of a current that flows through the plurality of thermoelectric conversion elements 3 is reversed between the pair of terminals 4a and 4b when the thermoelectric conversion element 3 made of a p-type semiconductor is used.

Also, in the above-described embodiment, a configuration in which the first heat transfer plate 11 disposed on the above-described high-temperature (heating) side is thermally connected with the hot junction side electrode 9 via the heat transfer part 12 (the protrusion 12a) is provided. However, in contrast, a configuration in which the first heat transfer plate 11 disposed on the low-temperature (heat radiation/cooling) side is thermally connected with the cold junction side electrode 10 via the heat transfer part 12 (the protrusion 12a) may be provided. In this case, the second surface 2b of the substrate 2 may be disposed on the high-temperature (heating) side.

Also, although a configuration in which one substrate 2 on which the plurality of thermoelectric conversion elements 3 are disposed is sandwiched between the first heat transfer plate 11 and the second heat transfer plate 14 described above is an exemplary example of the above-described embodiment, a plurality of substrates 2 on which the plurality of thermoelectric conversion elements 3 are disposed may be sandwiched between the first heat transfer plate 11 and the second heat transfer plate 14.

As described above, in the thermoelectric conversion device to which the present disclosure is applied, it is possible to suppress loss when a current generated by each thermoelectric conversion element flows through wiring by shortening the entire length of wiring to be drawn between thermoelectric conversion elements and reducing the entire resistance of wiring. As a result, the output of the thermoelectric conversion device can be improved.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the disclosure. Accordingly, the invention is not to be considered as being limited by the foregoing description, and is only limited by the scope of the appended claims.

What is claimed is:

1. A thermoelectric conversion device comprising:
a base material having a first surface and a second surface facing each other in a thickness direction;
thermoelectric conversion element arrays each having thermoelectric conversion elements lined up in a first direction among the first direction and a second direction intersecting each other in a plane on the first surface side of the base material, the thermoelectric conversion element arrays being disposed in a row in the second direction;
first electrodes, each of which is provided at one end side of each thermoelectric conversion element constituting the thermoelectric conversion element array in the second direction and second electrodes, each of which is provided at other end side of the each thermoelectric conversion element in the second direction;
first wirings, each of which is disposed between one thermoelectric conversion element and other thermoelectric conversion element adjacent in the first direction and electrically connected between the first electrodes or the second electrodes of the one thermoelectric conversion element and the other thermoelectric conversion element such that the thermoelectric conversion elements constituting the thermoelectric conversion element array are connected in series; and
second wirings, each of which is electrically connected between the first electrodes or the second electrodes of the thermoelectric conversion elements located at one-end-most sides or other-end-most sides of one thermoelectric conversion element array and other thermoelectric conversion element array in the first direction such that thermoelectric conversion elements constituting the one thermoelectric conversion element array and thermoelectric conversion elements constituting the other thermoelectric conversion element array adjacent to the one thermoelectric conversion element array in the second direction are connected to each other in series.

2. The thermoelectric conversion device according to claim 1, wherein, in the thermoelectric conversion elements constituting the thermoelectric conversion element array, thermoelectric conversion elements which have opposite current flow directions between the first electrodes and second electrodes are alternately disposed in a row in the first direction.

3. The thermoelectric conversion device according to claim 1, wherein, in the thermoelectric conversion elements constituting the thermoelectric conversion element array, thermoelectric conversion elements which have opposite current flow directions between the first electrodes and second electrodes are alternately disposed in a row in the second direction.

4. The thermoelectric conversion device according to claim 2, wherein, in the thermoelectric conversion elements constituting the thermoelectric conversion element array, thermoelectric conversion elements which have opposite current flow directions between the first electrodes and second electrodes are alternately disposed in a row in the second direction.

5. The thermoelectric conversion device according to claim 1, wherein, in the first electrodes and the second electrodes of the each thermoelectric conversion element constituting the thermoelectric conversion element array, electrodes located at hot junction sides and electrodes located at cold junction sides are alternately disposed in a row in the first direction.

6. The thermoelectric conversion device according to claim 2, wherein, in the first electrodes and the second electrodes of the each thermoelectric conversion element constituting the thermoelectric conversion element array, electrodes located at hot junction sides and electrodes located at cold junction sides are alternately disposed in a row in the first direction.

7. The thermoelectric conversion device according to claim 3, wherein, in the first electrodes and the second electrodes of the each thermoelectric conversion element constituting the thermoelectric conversion element array, electrodes located at hot junction sides and electrodes located at cold junction sides are alternately disposed in a row in the first direction.

8. The thermoelectric conversion device according to claim 4, wherein, in the first electrodes and the second electrodes of the each thermoelectric conversion element constituting the thermoelectric conversion element array, electrodes located at hot junction sides and electrodes located at cold junction sides are alternately disposed in a row in the first direction.

9. The thermoelectric conversion device according to claim 1, wherein the first electrodes or the second electrodes of the one thermoelectric conversion element and the other thermoelectric conversion element are electrically connected via the first wiring lined up on an identical straight line as the first electrode or the second electrode.

10. The thermoelectric conversion device according to claim 2, wherein the first electrodes or the second electrodes of the one thermoelectric conversion element and the other thermoelectric conversion element are electrically connected via the first wiring lined up on an identical straight line as the first electrode or the second electrode.

11. The thermoelectric conversion device according to claim 3, wherein the first electrodes or the second electrodes of the one thermoelectric conversion element and the other thermoelectric conversion element are electrically connected via the first wiring lined up on an identical straight line as the first electrode or the second electrode.

12. The thermoelectric conversion device according to claim 4, wherein the first electrodes or the second electrodes of the one thermoelectric conversion element and the other thermoelectric conversion element are electrically connected via the first wiring lined up on an identical straight line as the first electrode or the second electrode.

13. The thermoelectric conversion device according to claim 5, wherein the first electrodes or the second electrodes of the one thermoelectric conversion element and the other thermoelectric conversion element are electrically connected via the first wiring lined up on an identical straight line as the first electrode or the second electrode.

14. The thermoelectric conversion device according to claim 1, further comprising a first heat transfer member disposed on the first surface side of the base material,
wherein the first heat transfer member is thermally connected with the first electrode and the second electrode configured to be either one of a hot junction side and a cold junction side via a heat transfer part.

15. The thermoelectric conversion device according to claim 2, further comprising a first heat transfer member disposed on the first surface side of the base material,
wherein the first heat transfer member is thermally connected with the first electrode and the second electrode configured to be either one of a hot junction side and a cold junction side via a heat transfer part.

16. The thermoelectric conversion device according to claim 3, further comprising a first heat transfer member disposed on the first surface side of the base material,
wherein the first heat transfer member is thermally connected with the first electrode and the second electrode configured to be either one of a hot junction side and a cold junction side via a heat transfer part.

17. The thermoelectric conversion device according to claim 4, further comprising a first heat transfer member disposed on the first surface side of the base material,
wherein the first heat transfer member is thermally connected with the first electrode and the second electrode configured to be either one of a hot junction side and a cold junction side via a heat transfer part.

18. The thermoelectric conversion device according to claim 5, further comprising a first heat transfer member disposed on the first surface side of the base material,
wherein the first heat transfer member is thermally connected with the first electrode and the second electrode configured to be either one of a hot junction side and a cold junction side via a heat transfer part.

19. The thermoelectric conversion device according to claim 9, further comprising a first heat transfer member disposed on the first surface side of the base material,
wherein the first heat transfer member is thermally connected with the first electrode and the second electrode configured to be either one of a hot junction side and a cold junction side via a heat transfer part.

20. The thermoelectric conversion device according to claim 14, further comprising a second heat transfer member disposed on the second surface side of the base material and thermally connected with the base material.
